(19) United States
(12) Patent Application Publication
(10) Pub. No.: US 2021/0189076 A1
(43) Pub. Date: Jun. 24, 2021

(54) SILICONE FILM WITH GAS BARRIER PROPERTIES

(71) Applicant: BenQ Materials Corporation, Taoyuan (TW)

(72) Inventors: Shih-Chieh Teng, Taoyuan (TW); Ju-Hui Huang, Taoyuan (TW)

(21) Appl. No.: 16/807,201

(22) Filed: Mar. 3, 2020

(30) Foreign Application Priority Data
Dec. 24, 2019 (TW) 108144308

(51) Int. Cl. C08J 5/18; C08L 83/04; C08K 3/34; C23C 14/10; C23C 14/08; C23C 16/455; C23C 16/40; C08K 3/36; H01L 33/56; C08G 77/18; C08G 77/12; C08K 3/38; C08K 3/32

(52) U.S. Cl. CPC C08J 5/18; C08L 2203/16; C08K 3/346; C23C 14/10; C23C 14/083; C23C 14/081; C23C 16/45525; C23C 16/403; C23C 16/401; C23C 16/405; C08K 3/36; H01L 33/56; C08G 77/18; C08G 77/12; C08K 3/38; C08K 3/32; C08K 2003/325; C08K 2201/005; C08J 2383/05; C08J 2383/06; C08K 2003/385; C08L 2203/206; C08L 83/04

(57) ABSTRACT

The disclosure provides a silicone resin film with water vapor barrier property formed by curing a curable silicone resin composition, wherein the curable silicone resin composition comprises 10 to 25 parts by weight of a linear polysiloxane; 40 to 55 parts by weight of a first silicone resin wherein the first silicone resin have at least following siloxane units represented by the general formulas: R¹SiO_{3/2} and R²₂SiO_{2/2}, wherein the molar fraction of R¹SiO_{3/2} unit is present in the range of 0.60 to 0.75 in the general formula; 15 to 30 parts by weight of a second silicone resin; 15 to 25 parts by weight of a polysiloxane having silicon-hydrogen bond; 10 to 40 parts by weight of microsheets; and a platinum group metal catalyst.

This application claims the benefit of Taiwanese application serial No. 108144308, filed on Dec. 24, 2019, the subject matter of which is incorporated herein by reference.

### BACKGROUND OF THE INVENTION

### Field of the Invention

The present disclosure is directed to a silicone resin film for encapsulating optical semiconductor devices and particularly a silicone resin film for encapsulating light emitting diode (LED) devices.

### Description of the Related Art

Comparing to traditional lighting devices, LEDs are widely developed because they are advantages of small size, high lighting efficiency, long working life, high safety, high response time, rich colors, no heat radiation and no mercury or other poisons polluted to environment. LEDs can be widely used in lighting for buildings, consumptive handheld lighting devices, retailed displaying light devices and housing lighting devices.

Conventional LED package comprises a lead frame, a LED chip and an encapsulated gel. Silicone resins are widely used as the encapsulation gels because of their excellent heat-resistance and light-resistance. However, the Si—O—Si bonding angle in the silicone resin is large, which will result in poor water vapor barrier property of the silicone resin, and phosphors or quantum dots in the LED package will be prone to be wetted and led to the decay of color or emitting light. Although, it is known that the water vapor barrier property of the silicone resin can be enhanced by increasing the cross-link density thereof or adding nanoparticles, but the enhancing effect is limited. In addition, because of higher Coefficient of Thermal Expansion (CTE) of the silicone resin, which will result in greater thermal stress and cause a compact inorganic thin film not be easily formed on the surface of the silicone resin during the inorganic thin film coating process. Therefore, it is not suggested to enhance the water vapor barrier property of the silicone film by coating an inorganic thin film on the surface thereof.

Conventional gas barrier is formed by coating an Al₂O₃ layer on a polymer substrate with a better water vapor barrier property such as PET or PEN substrate by atomic layer deposition. However, the flexibility and the molding ability of PET or PEN are not good enough to be applied in high-end LEDs encapsulated by chip scale package technology.

Therefore, a novel silicone resin film with water vapor barrier property is demanded to provide enough water vapor barrier property and high workability for packaging LEDs, and maintain necessary optical properties for LED encapsulation.

### SUMMARY OF THE INVENTION

The present invention provides a silicone resin film with water vapor barrier property, which provides enough water vapor barrier property and high workability for packaging LEDs by so-called chip scale package (CSP) process, and maintains necessary optical properties such as high visible light transmittance and low haze for LED encapsulation.

The present invention provides a silicone resin film with water vapor barrier property, which is formed by curing a curable silicone resin composition, wherein the curable silicone resin composition comprising: 10 to 25 parts by weight of a linear polysiloxane, wherein the average composition formula of the linear polysiloxane have at least one aryl group bonded to a silicon atom and two alkenyl groups bonded to a silicon atom; 40 to 55 parts by weight of a first silicone resin, wherein the first silicone resin have at least following unit represented by the general formulas: R¹SiO_{3/2} and R²₂SiO_{2/2}, R¹ and R² are independently substituted or unsubstituted alkyl group, substituted or unsubstituted alkenyl group, or substituted or unsubstituted aryl group, and the molar fraction of R¹SiO_{3/2} unit is present in the range of 0.60 to 0.75 in the general formula, and the molar ratio of the alkenyl groups bonded to Si atoms to the functional groups bonded to Si atoms is in the range of 0.03 to 0.15; 15 to 30 parts by weight of a second silicone resin, wherein the second silicone resin have at least following units represented by the general formulas: R³SiO_{3/2} and R⁴₃SiO_{1/2}, R³ and R⁴ are independently substituted or unsubstituted alkyl group, substituted or unsubstituted alkenyl group, or substituted or unsubstituted aryl group; 15 to 25 parts by weight of a polysiloxane having silicon-hydrogen bond represented by the general formula as HR⁵₂SiO(SiR⁶₂O)ₙSiR⁵₂H, wherein R⁵ is a substituted or unsubstituted alkyl group or hydrogen, R⁶ is a substituted or unsubstituted aryl group or alkyl group, n is an integer greater or equal to 0; 10 to 40 parts by weight of microsheets; and a platinum group metal catalyst; wherein, the water vapor transmission rate (WVTR) of the silicone resin film with water vapor barrier property is less than 40 gm⁻² day⁻¹, the visible light transmittance of the silicone resin film with water vapor barrier property is greater than 92%, and the haze of the silicone resin film with water vapor barrier property is less than 4%.

In one embodiment of the silicone resin film with water vapor barrier property, wherein the aspect ratio of each microsheet is in the range of 10 to 200, and the length of each microsheet is in the range of 0.1 μm to 25 μm.

In one embodiment of the silicone resin film with water vapor barrier property, wherein the microsheets can be selected from at least one of the group consisting of mica, clay, layered double hydroxide, calcium hydrogen phosphate and boron nitride, or combinations thereof.

In one embodiment of the silicone resin film with water vapor barrier property, wherein the coefficient of thermal expansion (CTE) at 25° C. to 50° C. is in the range of 20 ppm to 60 ppm, the coefficient of thermal expansion (CTE) at 80° C. to 100° C. is in the range of 50 ppm to 150 ppm, and the arithmetical mean height (Sa) is in the range of 0.01 μm to 0.15 μm.

In another embodiment of the silicone resin film with water vapor barrier property, wherein the curable silicone resin composition can further comprise a bonding agent, an inhibitor, a thixotropic agent, an anti-setting agent, an inorganic filler, a phosphor, or combinations thereof.

In another embodiment of the silicone resin film with water vapor barrier property, wherein the inorganic filler further comprises a fumed silica.

In further another embodiment of the silicone resin film with water vapor barrier property, further comprises an inorganic coating layer formed on the surface of the silicone resin film with water vapor barrier property.

In further another embodiment of the silicone resin film with water vapor barrier property, wherein the inorganic coating layer is formed on the surface of the silicone resin film with water vapor barrier property by sputter deposition or atomic layer deposition.

In further another embodiment of the silicone resin film with water vapor barrier property, wherein the thickness of the inorganic coating layer is in the range of 10 nm to 300 nm.

In further another embodiment of the silicone resin film with water vapor barrier property, wherein the inorganic coating layer includes SiO₂, Al₂O₃ or HfO₂.

In further another embodiment of the silicone resin film with water vapor barrier property, wherein the water vapor transmission rate (WVTR) of the silicone resin film with water vapor barrier property is less than 0.5 gm⁻² day⁻¹.

This invention provides an optical semiconductor device, which is encapsulated by one of above-mentioned silicone resin films with water vapor barrier property.

### DETAILED DESCRIPTION OF THE INVENTION

These and other aspects of the invention will become apparent from the following description of the presently preferred embodiments. The detailed description is merely illustrative of the invention and does not limit the scope of the invention, which is defined by the appended claims and equivalents thereof. As would be obvious to one skilled in the art, many variations and modifications of the invention may be affected without departing from the spirit and scope of the novel concepts of the disclosure.

The detailed description provided below in connection with the appended drawings is intended as a description of the present examples and is not intended to represent the only forms in which the present example may be constructed or utilized. The description sets forth the functions of the example and the sequence of steps for constructing and operating the example. However, the same or equivalent functions and sequences may be accomplished by different examples.

In the following description, numerous specific details are described in detail in order to enable the reader to fully understand the following examples. However, embodiments of the present invention may be practiced in case no such specific details.

Unless defined otherwise, all technical and scientific terms used herein have the same meaning as commonly understood by one of ordinary skill in the art to which this invention belongs. Generally, the nomenclature used herein and the laboratory procedures are well known and commonly employed in the art. Conventional methods are used for these procedures, such as those provided in the art and various general references. Where a term is provided in the singular, the inventors also contemplate the plural of that term. The nomenclature used herein and the laboratory procedures described below are those well-known and commonly employed in the art.

The silicone resin film with water vapor barrier property according to this present invention is formed by curing a curable silicone resin composition, wherein the curable silicone resin composition comprising: 10 to 25 parts by weight of a linear polysiloxane, wherein the average composition formula of the linear polysiloxane have at least one aryl group bonded to a silicon atom and two alkenyl groups bonded to a silicon atom; 40 to 55 parts by weight of a first silicone resin, wherein the first silicone resin have at least following unit represented by the general formulas: R¹SiO_{3/2} and R²₂SiO_{2/2}, R¹ and R² are independently substituted or unsubstituted alkyl group, substituted or unsubstituted alkenyl group, or substituted or unsubstituted aryl group, and the molar fraction of R¹SiO_{3/2} unit is present in the range of 0.60 to 0.75 in the general formula, and the molar ratio of the alkenyl groups bonded to Si atoms to the functional groups bonded to Si atoms is in the range of 0.03 to 0.15; 15 to 30 parts by weight of a second silicone resin, wherein the second silicone resin have at least following units represented by the general formulas: R³SiO_{3/2} and R⁴₃SiO_{1/2}, R³ and R⁴ are independently substituted or unsubstituted alkyl group, substituted or unsubstituted alkenyl group, or substituted or unsubstituted aryl group; 15 to 25 parts by weight of a polysiloxane having silicon-hydrogen bond represented by the general formula as HR⁵₂SiO(SiR⁶₂O)ₙSiR⁵₂H, wherein R⁵ is a substituted or unsubstituted alkyl group or hydrogen, R⁶ is a substituted or unsubstituted aryl group or alkyl group, n is an integer greater or equal to 0; 10 to 40 parts by weight of microsheets; and a platinum group metal catalyst.

The water vapor transmission rate (WVTR) of the silicone resin film with water vapor barrier property can be enhanced by adding certain ratio of microsheets in the curable silicone resin of the silicone film with water vapor barrier property of the present invention, and the optical properties for packaging LEDs such as high visible light transmittance and low haze, and workability of the silicone resin film with water vapor barrier property can still be maintained.

According to one embodiment of this invention, suitable microsheets can be, for example, at least one of mica, clay, layered double hydroxide, calcium hydrogen phosphate and boron nitride, or combinations thereof. The aspect ratio of each microsheet is in the range of 10 to 200, and preferably in the range of 50 to 200. The length of each microsheet is in the range of 0.1 μm to 25 μm, and preferably in the range of 2 μm to 25 μm. The thickness of the inorganic coating layer is in the range of 10 nm to 1000 nm, and preferably in the range of 10 nm to 400 nm.

According to one embodiment of this invention, the microsheets within the curable silicone resin can be further modified by silicone to enhance its hydrophobic property to prevent microsheets within the curable silicone resin from being aggregated. In a preferred embodiment of this invention, the microsheets within the curable silicone resin can be a methyl silicon modified mica microsheets.

The content of microsheets within the curable silicone resin is in the range of 10 to 40 parts by weight. When the content of microsheets within the curable silicone resin is too high, the haze of the the silicone resin film with water vapor barrier property will be increased which will result in decreasing the emitting efficiency of LEDs. When the content of microsheets within the curable silicone resin is too low, the water vapor transmission rate (WVTR) of the silicone resin film with water vapor barrier property can't be enhanced, and the Coefficient of Thermal Expansion (CTE) of the silicone can't be effectively decreased, which will result in crack during subsequently coating for the inorganic coating layer and provide insufficient water vapor barrier property.

According to one embodiment of this invention, the first silicone resin have at least following unit represented by the general formulas: R¹SiO_{3/2} and R²₂SiO_{2/2}, R¹ and R² are independently substituted or unsubstituted alkyl group, substituted or unsubstituted alkenyl group such as vinyl group, acryl group, allyl group, butenyl group, pentenyl group, or hexenyl group, and preferably vinyl group, or substituted or unsubstituted aryl group, such as phenyl group tolyl group, xylyl group, or naphthyl group, and preferably phenyl group. Except the substituted or unsubstituted alkyl group, substituted or unsubstituted alkenyl group, or substituted or unsubstituted aryl group, those function groups bonded to Si atoms can be substituted or unsubstituted alkyl group such as methyl group, ethyl group, propyl group, butyl group, isobutyl group, tert-butyl group, pentyl group, neopentyl group, hexyl group, cyclohexyl group, octyl group, nonyl group or decyl group, and preferably methyl group.

According to one embodiment of this invention, in order to enhance the heat-resistance and hardness of the silicone resin film with water vapor barrier property, in the average unit of first silicone resin, the molar ratio of the aryl groups bonded to Si atoms to all functional groups bonded to Si atoms, excluding the end-cap functional groups, is at least greater than 0.48. The weight average molecular weight of the first silicone resin is in the range of 500 to 200,000, and preferably in the range of 1,000 to 190,000.

According to one embodiment of this invention, the average unit of the first silicone resin can be represented as (PhSiO_{3/2})_{0.7}(Me₂SiO_{2/2})_{0.15}(ViMeSiO_{2/2})_{0.15} and end-capped with ViMe₂SiO_{1/2} unit, wherein Ph represents the phenyl group, Me represents the methyl group, and Vi represents the vinyl group.

According to another embodiment of this invention, the average unit of the first silicone resin can be represented as (PhSiO_{3/2})_{0.7}(Me₂SiO_{2/2})_{0.2}(ViMeSiO_{2/2})_{0.1} end-capped with ViMe₂SiO_{1/2} unit.

Furthermore, in the curable silicone resin composition for forming the silicone resin film, the use of the linear polysiloxane is for improving the processing of silicone resin of the first silicone resin and the second silicone resin and enhancing the flexibility of the silicone resin film obtained. According to one embodiment of this invention, the average unit of the linear polysiloxane comprises at least an aryl groups bonded to a silicon atom and an alkenyl group bonded to two silicon atoms. The aryl group can be an aryl group substituted or unsubstituted by such as, phenyl, tolyl, xylyl or naphthyl and preferably by phenyl. The alkenyl groups can be substituted or unsubstituted alkenyl groups such as vinyl, propenyl, allyl, butenyl, pentenyl or hexenyl and preferably by vinyl group, in addition to the aryl group and the alkenyl group, the groups that can be bonded to silicon atoms are substituted or unsubstituted alkyl groups such as methyl, ethyl, propyl, isopropyl, butyl, isobutyl, tert-butyl pentyl neopentyl, hexyl, cyclohexyl octyl, nonyl or decyl, preferably methyl.

In order to enhance the heat-resistance, hardness and refractivity of the silicone resin film with water vapor barrier property, in the average composition formula of the linear polysiloxane in the curable silicone resin, the molar ratio of the aryl groups bonded to Si atoms to all functional groups bonded to Si atoms, excluding the end-capped functional groups, is at least greater than 0.4. The content of the linear polysiloxane can be in the range of 10 to 25 parts by weight, and preferably 14 to 20 parts by weight

In a preferred embodiment of the present disclosure, the average composition formula of the linear polysiloxane is represented as (PhMeSiO_{2/2})_{0.8}(Me₂SiO_{2/2})_{0.1}(ViMeSiO_{2/2})_{0.1} and end-capped with ViMe₂SiO_{1/2} unit, wherein Ph is phenyl group, Me is methyl group and Vi is vinyl group. In this example of the present disclosure, the weight average molecular weight of the linear polysiloxane is about 1,000 to 200,000 and preferably is about 1,000 to 160,000, and the viscosity of the linear polysiloxane at 25° C. is not limited and preferably about 6420 mPa·s.

In the curable silicone resin composition for forming a silicone film with water vapor barrier property, the average composition formula of the second silicone resin is represented by a monomer having at least R³SiO_{3/2} and R⁴₃SiO_{1/2}, wherein R³ is a substituted or unsubstituted aryl group, substituted or unsubstituted alkyl group or substituted or unsubstituted alkenyl group. R⁴ is a substituted or unsubstituted aryl group, a substituted or unsubstituted alkyl group or a substituted or unsubstituted alkenyl group. The substituted or unsubstituted aryl groups can be, for example, phenyl, tolyl, xylyl or naphthyl, and preferably phenyl. The substituted or unsubstituted alkenyl group can be, for example ethenyl, propenyl, allyl, butenyl, pentenyl or hexenyl and preferably ethenyl. In addition to the above-mentioned substituted or unsubstituted aryl groups and the substituted or unsubstituted alkenyl groups, the other functional groups bonded to the silicon atom can be substituted or unsubstituted alkyl group. The substituted or unsubstituted alkyl group can be, for example, methyl, ethyl, propyl, isopropyl, butyl, isobutyl, tert-butyl, pentyl, neopentyl, hexyl, cyclohexyl, octyl, nonyl or decyl, and preferably methyl.

For enhancing the heat-resistance, hardness and the refraction of the silicone resin film, in the second silicone resin of the curable silicone resin composition, the molar ratio of the aryl groups bonded to silicon atom to the all functional groups bonded to the silicon atom, excluding the end-cap functional groups, is at least 0.25.

For enhancing the heat-resistance, hardness and the refraction of the silicone resin film with water vapor barrier property, in the second silicone resin of the curable silicone resin composition, the molar ratio of the aryl groups bonded to silicon atom to the all functional groups bonded to the silicon atom, excluding the end-cap functional groups, is at least 0.25.

In an embodiment of the present disclosure, the average composition formula of the second silicone resin can be represented by (PhSiO_{3/2})_{0.5}(ViMe₂SiO_{1/2})_{0.5}, wherein Ph is phenyl group. Me is methyl group and Vi is vinyl group. The weight average molecular weight of the second silicone resin is about 100 to 10,000 and preferably is about 500 to 5,000.

In the curable silicone resin composition for forming the silicone resin film with water vapor barrier property, the polysiloxane having silicon-hydrogen bond is represented as HR⁵₂SiO(SiR⁶₂O)ₙSiR⁵₂H, wherein R⁵ is substituted or unsubstituted alkyl groups or hydrogen, R⁶ is substituted or unsubstituted aryl groups or substituted or unsubstituted alkyl groups, and n is an integer more than 0.

The above mentioned substituted or unsubstituted aryl groups can be, for example, phenyl, tolyl, xylyl or naphthyl, and preferably phenyl. The above mentioned substituted or substituted alkyl groups can be, for example, methyl, ethyl, propyl, isopropyl, butyl, isobutyl, tert-butyl, pentyl, neopentyl, hexyl, cyclohexyl, octyl, nonyl or decyl, and preferably methyl.

In an embodiment of the present disclosure, the average unit formula of the polysiloxane having silicon-hydrogen bond can be represented as (Ph₂SiO_{2/2})₁(HMe₂SiO_{1/2})₂, wherein Ph is phenyl group and Me is methyl group. The weight average molecular weight of the polysiloxane having silicon-hydrogen bond is about 100 to 5,000 and preferably is about 100 to 1,000.

In the curable silicone resin composition of one embodiment of the present disclosure, the platinum group metal catalyst can be for example, platinum based catalyst, rhodium based catalyst or palladium based catalyst, and preferably is platinum based catalyst. The common used catalysts can be, for example, H₂PtCl₆. mH₂O, K₂PtCl₆, KHPtCl₆.mH₂O, K₂PtCl₄, K₂PtCl₄.mH₂O or PtO₂.mH₂O (m is an positive integer). The complex of these catalysts with olefin, alcohol or organopolysiloxane containing vinyl groups can be also used, for example platinum(0)-2,4,6,8-tetramethyl-2,4,6,8-tetravinylcyclotrasiloxane complex solution or Platinum-Octanal/Octanol complex, but not limited to these compounds. These platinum group metal catalysts can be used alone or in combination. The addition amount of the platinum group metal catalyst is in the range of about 1 ppm to 50 ppm on the total weight of the linear polysiloxane, the first silicone resin, the second silicone resin and the polysiloxane having silicon-hydrogen bond, and preferably is in the range of about 3 ppm to about 10 ppm.

According to one embodiment of this invention, the platinum group metal catalyst is Platinum-Octanal/Octanol complex. The addition amount of the catalyst is about 4.3 ppm on the basis of the total weight of the linear polysiloxane, the first silicone resin, the second silicone resin and the polysiloxane having silicon-hydrogen bond.

The curable silicone resin composition of the silicone resin film with water vapor barrier property according to this invention can further compris a bonding agent, an inhibitor, a thixotropic agent, an anti-setting agent, an inorganic filler, a phosphor, or combinations thereof.

The above-mentioned inorganic fillers are used to enhance the heat-resistance of the silicone resin film with water vapor barrier property, and also be used to prevent phosphor from setting and act as reflective particles. The inorganic fillers can be enhanced inorganic filler, for example, but not limited to fumed silica and gas-phase titanium dioxide, or non-enhanced inorganic fillers, for example, but not limited to calcium carbonate, silicon carbonate, titanium dioxide, titanium oxide and zinc oxide.

According to one embodiment of this invention, the curable silicone resin of the silicone resin film with water vapor barrier property further comprises 0.1 to 5 parts by weight of fumed silica relative to 100 parts by weight of the total amount of the linear polysiloxane, the first silicone resin, the second silicone resin and the polysiloxane having silicon-hydrogen bond.

The silicone resin film with water vapor barrier property according to this invention has excellent water vapor barrier property and proper optical properties, wherein the water vapor barrier property thereof is less than 40 gm⁻² day⁻¹, visible light transmittance is greater than 92%, and the haze is less than 4%. Besides, the silicone resin film with water vapor barrier property according to this invention has excellent workability, wherein the coefficient of thermal expansion (CTE) thereof at 25° C. to 50° C. is in the range of 20 ppm to 60 ppm, the coefficient of thermal expansion (CTE) thereof at 80° C. to 100° C. is in the range of 50 ppm to 150 ppm, and the arithmetical mean height (Sa) thereof is in the range of 0.01 μm to 0.15 μm, which are beneficial to the subsequent forming of the inorganic coating layer.

According to another embodiment of this invention, the silicone resin film with water vapor barrier property, further comprises an inorganic coating layer formed on the surface of the silicone resin film with water vapor barrier property to further reduce its water vapor barrier property.

The inorganic coating layer can comprise but not limited to SiO₂, Al₂O₃ or HfO₂. According to one embodiment of this invention, the inorganic coating layer is a SiO₂ coating layer and according to another embodiment of this invention, the inorganic coating layer is an Al₂O₃/HfO₂ coating layer.

The inorganic coating layer is formed on the surface of the silicone resin film with water vapor barrier property by sputter deposition or atomic layer deposition.

According to one embodiment of the silicone resin film with water vapor barrier property, wherein the thickness of the inorganic coating layer is in the range of 10 nm to 300 nm, and preferably in the range of 20 nm to 30 nm, and the water vapor transmission rate (WVTR) of the silicone resin film with water vapor barrier property is less than 0.5 gm⁻² day⁻¹.

This invention also provides an optical semiconductor device, which is encapsulated by one of above-mentioned silicone resin films with water vapor barrier property.

The following examples are intended to further illustrate the invention, but the invention is not limited thereto.

### EXAMPLES

### Preparation Example 1: Preparation of the Linear polysiloxane (Compound 1)

3499.92 g (19.13 moles) of phenylmethyl dimethoxysilane (commercially available from Chembidge, Taiwan), 288.48 g (2.4 moles) of dimethydimethoxysilane (commercially available from Chembidge, Taiwan), and 317.28 g (2.4 moles) of methylvinyldimethoxysilane (commercially available from Union Chemical Ind. Co., Ltd. (Union), Taiwan) were added to a reaction tank and mixed by stirring at ambient temperature to a homogenous solution. The mixed solution was dropped into a 5% aqueous sulfuric acid solution (5337.4 g) to obtain a reaction solution. Next, the reaction solution was heated to 75° C. to conduct a hydrolysis reaction. After the hydrolysis reaction was completed, the organic phase was extracted by deionized water until the organic phase reached a neutral state, and then removed the organic solvent to obtain a hydrolysis product.

The hydrolysis product, 69.52 g (0.374 mole) of divinyltetramethyldisiloxane (commercially available from Union) and 5.88 g of tetramethyl ammonium hydroxide (brand name L09658, commercially available from Alfa Aesar, USA) were placed into a reaction tank. Nitrogen was fed into the reaction tank and the mixture was stirred at ambient temperature to obtain a reaction solution. The reaction solution was heated to 95° C. After the reaction was completed, the reaction solution was conducted an alkaline removing to complete the preparation of Compound 1. The average composition formula of the Compound 1 is (PhMeSiO_{2/2})_{0.8}(Me₂SiO_{2/2})_{0.1}(ViMeSiO_{2/2})_{0.1} with end-capped unit ViMe₂SiO_{1/2}, wherein Ph represents phenyl group, Me represents methyl group and Vi represents vinyl group.

### Preparation Example 2: Preparation of the First silicone resin (Compound 2)

2685 g (13.5 mole) of phenyl-trimethoxysilane (commercially available from Union, Taiwan), 349 g (2.9 moles) of dimethyl dimethoxysilane (commercially available from Chembridg, Taiwan), and 384 g (2.9 moles) of methylvinyldimethoxysilane (commercially available from Union, Taiwan) were placed in a reaction tank. The mixture was stirred at ambient temperature to obtain a homogenous solution. The mixed solution was dropped into 5% aqueous sulfuric acid solution (4579 g) to prepare a reaction solution. Then, this reaction solution was heated to 75° C. to conduct a hydrolysis reaction. After the reaction completed, the organic phase was extracted by deionized water until the organic phase reached neutral state, and then removed the solvent to obtain a hydrolysis product.

The hydrolysis product, 21.39 g (0.11 moles) of divinyltetramethyldisiloxane (commercially available from Union), 22.74 g of potassium hydroxide and 2274 g of toluene were placed into a reaction tank. Nitrogen was fed into the reaction tank and the mixture was stirred at ambient temperature to obtain a reaction solution. Next, the reaction solution was heated to 95° C. After the reaction was completed, the organic phase was extracted by deionized water until the organic phase reached neutral state, and then removed the solvent to obtain Compound 2. The average composition formula of Compound 2 was (PhSiO_{3/2})_{0.7}(Me₂SiO_{2/2})_{0.15}(ViMeSiO_{2/2})_{0.15} with end-capped unit ViMe₂SiO_{1/2}.

### Preparation Example 3: Preparation of the First silicone resin (Compound 3)

2776 g (14 moles) of phenyl-trimethoxysilane (commercially available from Union, Taiwan), 480.88 g (4 moles) of dimethyldimethoxysilane, commercially available from Chembridge, Taiwan), and 264.46 g (2 moles) of methylvinyldimethoxysilane (commercially available from Union, Taiwna) were placed into a reaction tank. The mixture was stirred at ambient temperature until obtaining a homogenous solution. The mixed solution was dropped into 5% aqueous sulfuric acid solution to prepare a reaction solution. Then, this mixture solution was heated to 75° C. to conduct hydrolysis. After the reaction was completed, the organic phase was extracted by deionized water until the organic phase reached neutral state, and next, removed solvent to obtain a hydrolysis product.

The hydrolysis product, 21.39 g (0.11 mole) of divinyltetramethyldisiloxane (commercially available from Union, Taiwan), 22.74 g of potassium hydroxide and 2274 g of toluene were placed into a reaction tank. Nitrogen was fed into the reaction tank and the mixture was stirred at ambient temperature to prepare a reaction solution. Then, the reaction solution was heated to 95° C. After the reaction was completed, the organic phase was extracted by deionized water until the organic phase reached neutral state and then, the solvent was removed to obtain Compound 3. The average composition formula of Compound 3 is (PhSiO_{3/2})_{0.7}(Me₂SiO_{2/2})_{0.02}(ViMeSiO_{2/2})_{0.1} with end-capped unit ViMe₂SiO_{1/2}.

### Preparation Example 4: Preparation of the Second Silicone Resin (Compound 4)

2379.4 g (12 moles) of phenyl-trimethoxysilane (commercially available from Union, Taiwan) and 1118.4 g (6 moles) of divinyltetramethyldisiloxane (commercially available from Union, Taiwan) were placed into a reaction tank. The mixture was stirred at ambient temperature until obtaining a homogenous solution. The mixed solution was dropped into 5% aqueous sulfuric acid solution (4547.16 g) to prepare a reaction solution. Then, this mixture solution was heated to 75° C. to conduct hydrolysis. After the reaction was completed, the organic phase was extracted by deionized water until the organic phase reached neutral state and next, removed solvent to obtain a hydrolysis product.

The hydrolysis product, 1998 g of toluene and 10 g of potassium hydroxide were placed into a reaction tank. Nitrogen was fed into the reaction tank and the mixture was stirred at ambient temperature to prepare a reaction solution. Then, the reaction solution was heated to 85° C. After the reaction was completed, the organic phase was extracted by deionized water until the organic phase reached neutral and then, the solvent was removed to obtain Compound 4. The average composition formula of Compound 4 is (PhSiO_{3/2})_{0.5}(ViMe₂SiO_{1/2})_{0.5}.

### Preparation Example 5: Preparation of polysiloxane having silicon-hydrogen Bond (Compound 5)

3432.04 g (14 moles) of diphenyldimethoxysilane (commercially available from Union, Taiwan), and 1880.62 g (14 moles) of 1,1,3,3-tetramethyldisiloxane (commercially available from Chembridge, Taiwan) were placed into a reaction tank. The mixture was stirred at ambient temperature until obtaining a homogenous solution. The mixed solution was dropped into 5% aqueous sulfuric acid solution (2669 g) to prepare a reaction solution. Then, this mixture solution was heated to 75° C. to conduct hydrolysis for 4 hours. After the reaction was completed, the organic phase was extracted by deionized water until the organic phase reached neutral state and then, the solvent was removed to obtain Compound 5. The average composition formula of the Compound 5 is (Ph₂SiO_{2/2})_{0.33}(HMe₂SiO_{1/2})_{0.67}.

### Example 1

Firstly, 47.3 g of Compound 2, 18.4 g of Compound 4, 20 g of Compound 5, 1000 ppm (based on 100 g of Compound 1, Compound 2, Compound 4 and Compound 5) of 1-ethynyl-cyclohexanol as an inhibitor, and 1.5 parts by weight of fumed silica (brand name TS-720, commercially available from Cabot Corp., USA) were placed into a reaction vessel to prepare a first solution. Into another reaction vessel, 14.3 g of Compound 1, and 4.3 ppm (based on 100 g of Compound 1, Compound 2, Compound 4 and Compound 5) of platinum-octanal/octanol complex (commercially available from Gelest, USA) were placed to prepare a second solution. The first solution, the second solution, 30 g of methyl silicone modified mica lamellas (commercially available from Alplus Company Limited, Taiwan), 30 g of toluene as solvent and equal amount of above mentioned materials zirconium beads with a thickness of 0.33 mm were mixed and stirred thoroughly by a Planetary Centrifugal Mixer (Thinky ARV-310), and then coated on a PET substrate and cured at 80° C. for 15 minutes and cured at 150° C. for 3 hours. Thereafter, a silicone resin film with a thickness of 50 μm can be obtained after the PET substrate was removed.

### Example 2

Another silicone resin film was manufactured by similar methods as mentioned in Example 1 except 40 g of methyl silicone modified mica lamellas (commercially available from Alplus Company Limited, Taiwan) and 35 g of toluene were introduced.

### Example 3

Firstly, 47.84 g of Compound 3, 19.53 g of Compound 4, 15.96 g of Compound 5, 2.05 g of Compound 6, 1000 ppm (based on 100 g of Compound 1, Compound 3, Compound 4, Compound 5 and Compound 6) of 1-ethynyl-cyclohexanol as an inhibitor, and 1.5 parts by weight of fumed silica (brand name TS-720, commercially available from Cabot Corp., USA) were placed into a reaction vessel to prepare a first solution. Into another reaction vessel, 14.53 g of Compound 1, and 4.3 ppm (based on 100 g of Compound 1, Compound 3, Compound 4, Compound 5 and Compound 6) of platinum-octanal/octanol complex (commercially available from Gelest, USA) were placed to prepare a second solution. The first solution, the second solution, 10 g of methyl silicone modified mica lamellas (commercially available from Alplus Company Limited, Taiwan), 10 g of toluene as solvent and equal amount of above mentioned materials zirconium beads with a thickness of 0.3 mm were mixed and stirred thoroughly by a Planetary Centrifugal Mixer (Thinky ARV-310), and then coated on a PET substrate and cured at 80° C. for 15 minutes and cured at 150° C. for 3 hours. Thereafter, a silicone resin film with a thickness of 50 μm can be obtained after the PET substrate was removed.

### Example 4

Another silicone resin film was manufactured by similar methods as mentioned in Example 3 except 30 g of methyl silicone modified mica lamellas (commercially available from Alplus Company Limited, Taiwan) and 37 g of toluene were introduced.

### Example 5

Another silicone resin film was manufactured by similar methods as mentioned in Example 3 except 40 g of methyl silicone modified mica lamellas (commercially available from Alplus Company Limited, Taiwan) and 37 g of toluene were introduced.

### Comparative Example 1

A silicone resin film was manufactured by similar methods as mentioned in Example 1 but no methyl silicone modified mica lamellas and toluene were introduced.

### Comparative Example 2

A silicone resin film was manufactured by similar methods as mentioned in Example 3 but no methyl silicone modified mica lamellas and toluene were introduced.

### Comparative Example 3

A silicone resin film was manufactured by similar methods as mentioned in Example 1 except 50 g of methyl silicone modified mica lamellas (commercially available from Alplus Company Limited, Taiwan) and 45 g of toluene were introduced.

The silicone resin films with water vapor barrier property according to this invention were measured by the evaluation methods as follows. The measurement results are shown in Table 1.

Measurement of Water Vapor Transmission Rate (WVTR)

The water vapor transmission rate (WVTR) was measured by Moconaquatran model 1 (Measurement range: 5-5×10⁻⁵ gm⁻² day⁻¹) according to ASTM F1249, at 25° C., with 90% relative humidity (RH). The sample size used for measurements was 0.5-5 cm².

Measurement of Coefficient of Thermal Expansion (CTE)

The Coefficient of Thermal Expansion (CTE) was measured by the Thermal Mechanical Analyzer (TMA from TA instrument) according to ASTM E831, at 30-100° C. increasing by 10° C./min, and under the tension of 0.0023N.

Measurement of Transmittance (T %)

The transmittance between wavelength of 380-700 nm was measured by the Spectrophotometer U4100 (from Hitachi, Japan).

Measurement of Haze

The Haze was measured by the Haze meter NDH2000 (from NIPPON DENS, Japan).

Measurement of Surface Roughness (Sa)

The arithmetical mean height (Sa) was measured by the Olympus OLS5000 3D laser microscope according to ISO25178 rule based on the laser confocal principle.

The properties of silicone resin films of Examples 1-5 and Comparative Example 1-2 are shown in Table 1 below:

TABLE 1
The properties of silicone resin films of
Examples 1-5 and Comparative Example 1-2

| | | | | | | Surface |
|---|---|---|---|---|---|---|
| | WVTR | 25-50° C. | 80-100° C. | Transmittance | Haze | Roughness |
| | (gm⁻²day⁻¹) | CTE(ppm) | CTE(ppm) | (%) | (%) | (μm) |
| Example. 1 | 18.88 | 37.7 | 144.5 | 97.19 | 0 | 0.039 |
| Example. 2 | — | 33.8 | 93.9 | 96.26 | 0 | 0.056 |
| Example. 3 | 38.64 | 56.5 | 140.4 | 98.43 | 0 | 0.014 |
| Example. 4 | 21.64 | 23.3 | 76.3 | 97.89 | 0 | 0.022 |
| Example. 5 | 17.78 | 22.4 | 52.4 | 97.41 | 3.38 | 0.112 |
| Comparative | 74.37 | 117.9 | 292.1 | 97.51 | 0 | 0.029 |
| Example. 1 | | | | | | |
| Comparative | 63.76 | 92.2 | 258.4 | 98.24 | 0 | 0.01 |
| Example. 2 | | | | | | |
| Comparative | 15.76 | 26.8 | 103 | 92.68 | 57.44 | 0.53 |
| Example. 3 | | | | | | |

As the measurement results shown in Table 1, the water vapor transmission rate (WVTR) of the silicone resin films of Examples 1 to 5 are all smaller than those of the silicone resin films of Comparative Examples 1 and 2 because microsheets were added into the silicone resin films of Examples 1 to 5. Besides, as shown in Table 1, the light transmittances of the silicone resin films of Examples 1 to 5 are all greater than 96%, and the hazes of the silicone resin films of Examples 1 to 4 all equal to 0, which demonstrate that the optical properties of the silicone resin films of Examples 1 to 5 according to this invention are excellent. Furthermore, as shown in Table 1, the Coefficient of Thermal Expansions (CTE) of the silicone resin films of Examples 1 to 5 are all lower than those of the silicone resin films of Comparative Examples 1 and 2, which demonstrate that the silicone resin films of Examples 1 to 5 can provide better workability for the inorganic coating layer formed thereafter.

### Example 6

An Al₂O₃ coating layer with a thickness of 50 nm was coated on the surface of the silicone resin film from Example 3 by sputtering according to Syskey Technology by using Ar as working gas at the working pressure of 0.005 torr

### Example 7

An Al₂O₃/HfO₂ coating layer with a thickness of 20 nm was coated on the surface of the silicone resin film from Example 3 by an i-SA (obtained from Syskey Technology, Taiwan) according to atomic layer deposition (ALD) technology by using Al(CH₃)₃ and tetrakis(ethylmethylamino)hafnium (TEMAHF) as precursors, using H₂O as the oxidant and using high purity nitrogen as the blowing gas and the carrier gas at the working pressure of 9 torr and at the temperature of 25° C.

### Example 8

An Al₂O₃/HfO₂ coating layer with a thickness of 20 nm was coated on the surface of the silicone resin film from Example 2 by the same atomic layer deposition (ALD) method described in Example 7.

The water vapor transmission rate (WVTR) of the silicone resin films of Examples 6 to 8 were measured and shown in Table 2.

TABLE 2
The water vapor transmission rate (WVTR) of
the silicone resin films of Examples 6 to 8

| | WVTR |
|---|---|
| | (gm⁻² day⁻¹) |
| Example. 6 | 0.453 |
| Example. 7 | 0.259 |
| Example. 8 | 0.161 |

As shown in Table 2, the water vapor transmission rate (WVTR) of the silicone resin films of Examples 6 to 8 are further decreased to less than 0.5 gm⁻² day′ after the inorganic coating layers were coated on the surfaces thereof. Therefore, the silicone resin films with water vapor barrier property according to this invention can provide both excellent water vapor barrier property and workability.

Although particular embodiments have been shown and described, it should be understood that the above discussion is not intended to limit the present invention to these embodiments. Persons skilled in the art will understand that various changes and modifications may be made without departing from the scope of the present invention as literally and equivalently covered by the following claims.

What is claimed is:

1. A silicone resin film with water vapor barrier property, which is formed by curing a curable silicone resin composition, wherein the curable silicone resin composition comprising:
10 to 25 parts by weight of a linear polysiloxane;
40 to 55 parts by weight of a first silicone resin, wherein the first silicone resin have at least following unit represented by the general formulas: R¹SiO_{3/2} and R²₂SiO_{2/2}, R¹ and R² are independently substituted or unsubstituted alkyl group, substituted or unsubstituted alkenyl group, or substituted or unsubstituted aryl group, and the molar fraction of R¹SiO_{3/2} unit is present in the range of 0.60 to 0.75 in the general formula, and the molar ratio of the alkenyl groups bonded to Si atoms to the functional groups bonded to Si atoms is in the range of 0.03 to 0.15;
15 to 30 parts by weight of a second silicone resin, wherein the second silicone resin have at least following units represented by the general formulas: R³SiO_{3/2} and R⁴₃SiO_{1/2}, R³ and R⁴ are independently substituted or unsubstituted alkyl group, substituted or unsubstituted alkenyl group, or substituted or unsubstituted aryl group;
15 to 25 parts by weight of a polysiloxane having silicon-hydrogen bond represented by the general formula as HR⁵₂SiO(SiR⁶₂O)ₙSiR⁵₂H, wherein R⁵ is a substituted or unsubstituted alkyl group or hydrogen, R⁶ is a substituted or unsubstituted aryl group or alkyl group, n is an integer greater or equal to 0;
10 to 40 parts by weight of microsheets; and
a platinum group metal catalyst;
wherein, the water vapor transmission rate (WVTR) of the silicone resin film with water vapor barrier property is less than 40 gm⁻² day⁻¹, the visible light transmittance of the silicone resin film with water vapor barrier property is greater than 92%, and the haze of the silicone resin film with water vapor barrier property is less than 4%.

2. The silicone resin film with water vapor barrier property as claimed in claim 1, wherein the aspect ratio of each microsheet is in the range of 10 to 200.

3. The silicone resin film with water vapor barrier property as claimed in claim 1, wherein the length of each microsheet is in the range of 0.1 μm to 25 μm.

4. The silicone resin film with water vapor barrier property as claimed in claim 1, wherein the microsheet is selected from at least one of the group consisting of mica, clay, layered double hydroxide, calcium hydrogen phosphate and boron nitride, or combinations thereof.

5. The silicone resin film with water vapor barrier property as claimed in claim 1, wherein the coefficient of thermal expansion at 25° C. to 50° C. is in the range of 20 ppm to 60 ppm, the coefficient of thermal expansion at 80° C. to 100° C. is in the range of 50 ppm to 150 ppm, and the arithmetical mean height (Sa) is in the range of 0.01 μm to 0.15 μm.

6. The silicone resin film with water vapor barrier property as claimed in claim 1, wherein the curable silicone resin composition further comprises an inhibitor, a thixotropic agent, an anti-setting agent, an inorganic filler, a phosphor, or combinations thereof.

7. The silicone resin film with water vapor barrier property as claimed in claim 6, wherein the inorganic filler further comprises a fumed silica.

8. The silicone resin film with water vapor barrier property as claimed in claim 1, further comprising an inorganic coating layer formed on the surface of the silicone resin film with water vapor barrier property.

9. The silicone resin film with water vapor barrier property as claimed in claim 8, wherein the inorganic coating layer is formed on the surface of the silicone resin film with water vapor barrier property by sputter deposition or atomic layer deposition.

10. The silicone resin film with water vapor barrier property as claimed in claim 8, wherein the thickness of the inorganic coating layer is in the range of 10 nm to 300 nm.

11. The silicone resin film with water vapor barrier property as claimed in claim 8, wherein the inorganic coating layer comprises SiO₂, Al₂O₃ or HfO₂.

12. The silicone resin film with water vapor barrier property as claimed in claim 8, wherein the water vapor transmission rate (WVTR) of the silicone resin film with water vapor barrier property is less than 0.5 gm⁻² day⁻¹.

13. An optical semiconductor device, which is encapsulated by the silicone resin film with water vapor barrier property claimed in claim 1.
